(19) United States
(12) Patent Application Publication
(10) Pub. No.: US 2025/0040130 A1
(43) Pub. Date: Jan. 30, 2025

(54) DOPING TECHNIQUES FOR MEMORY CELL SELECTION TRANSISTORS

(71) Applicant: Micron Technology, Inc., Boise, ID (US)

(72) Inventors: Kamal Karda, Boise, ID (US); Haitao Liu, Boise, ID (US); Scott E. Sills, Boise, ID (US); Si-Woo Lee, Boise, ID (US)

(21) Appl. No.: 18/773,001

(22) Filed: Jul. 15, 2024

Related U.S. Application Data
(60) Provisional application No. 63/528,821, filed on Jul. 25, 2023.

(51) Int. Cl. H10B 12/00

(52) U.S. Cl. CPC H10B 12/485; H10B 12/05; H10B 12/488

(57) ABSTRACT

Methods, systems, and devices for doping of memory cell selection transistors are described. Cell selection transistors of an array of memory cells may each include a semiconductor channel that is doped at a middle portion of the channel, which may support a deselection voltage for relatively high channel resistance that is relatively closer to or equal to a ground voltage than other transistor configurations. The semiconductor channels may include a p-type doping (e.g., using a configured concentration of boron) at a middle portion of the channels that is between end portions that are doped with an n-type doping (e.g., using phosphorous, arsenic, or a combination thereof, among other examples of n-type doping). In some implementations, undoped regions may be included between the n-type doped portions and the p-type doped portions. Such techniques may be implemented in horizontal cell selection transistors formed over a substrate, including for three-dimensional memory arrays.

### CROSS REFERENCE

The present application for patent claims the benefit of U.S. Provisional Patent Application No. 63/528,821 by KARDA et al., entitled “DOPING TECHNIQUES FOR MEMORY CELL SELECTION TRANSISTORS,” filed Jul. 25, 2023, assigned to the assignee hereof, and expressly incorporated by reference herein.

### TECHNICAL FIELD

The following relates to one or more systems for memory, including doping techniques for memory cell selection transistors.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a memory device that supports doping techniques for memory cell selection transistors in accordance with examples as disclosed herein.

FIG. 2 shows an example of an array architecture that supports doping techniques for memory cell selection transistors in accordance with examples as disclosed herein.

FIGS. 3A through 6B show examples of fabrication operations that support doping techniques for memory cell selection transistors in accordance with examples as disclosed herein.

FIG. 7 shows a flowchart illustrating a method or methods that support doping techniques for memory cell selection transistors in accordance with examples as disclosed herein.

### DETAILED DESCRIPTION

In some memory architectures, such as DRAM or FeRAM memory architectures, memory cells may each include a charge-storing memory element, such as a capacitor, and a cell selection transistor operable to couple the charge-storing memory element with an access line. In some examples, charge may leak to or from a charge-storing element through a cell selection transistor, which may be related to a channel resistance of the cell selection transistor while a deselection voltage is applied to a gate of the cell selection transistor (e.g., as a gate voltage). For example, relatively lower channel resistance during deselection may be associated with relatively higher leakage and relatively higher channel resistance during deselection may be associated with relatively lower leakage.

To support a relatively slower degradation of stored logic states associated with charge leakage, a deselection voltage for memory cells may be selected (e.g., configured) to provide a relatively high channel resistance (e.g., a peak channel resistance) and, therefore, a relatively low charge leakage through the cell selection transistors while deselected. In some cases, such as with an N—U—N cell selection transistor (e.g., associated with a semiconductor channel having an undoped portion between n-type doped portions), a deselection voltage for relatively high channel resistance may be a negative voltage (e.g., relative to a ground voltage). Although N—U—N cell selection transistors may be relatively easier to manufacture than other types of cell selection transistors, including for three-dimensional arrays of memory cells arranged over a substrate, maintaining a deselection voltage at a negative voltage may involve relatively higher power consumption or relatively higher complexity than maintaining the deselection voltage at other voltages, such as a ground voltage (e.g., 0V). Further, although a ground voltage may be implemented for a deselection voltage in such architectures (e.g., for a channel resistance that is less than a peak channel resistance), the relatively lower resistance, and corresponding higher rate of charge leakage, may involve relatively higher rates of refresh to restore a charge level of charge-storing memory elements, which may be associated with relatively higher power consumption, relatively higher latency, or relatively higher processor load associated with performing refresh operations.

In accordance with examples as disclosed herein, cell selection transistors for a three-dimensional array of memory cells may each include a semiconductor channel (e.g., a horizontal channel arranged above a substrate) that is doped at a middle portion of the channel, which may support a deselection voltage for relatively high channel resistance (e.g., peak channel resistance) that is relatively closer to or equal to a ground voltage than other transistor configurations. For example, the semiconductor channels may include a p-type doping (e.g., using a configured concentration of boron) at a middle portion of the channels that is between end portions that are doped with an n-type doping (e.g., using phosphorous, arsenic, or a combination thereof, among other examples of n-type doping), which may be implemented in a horizontal N—P—N cell selection transistor formed above a substrate. In some implementations, undoped regions of the semiconductor channels may be included between the n-type doped portions and the p-type doped portions (e.g., in an N—U—P—U—N cell selection transistor). In some examples, doping the middle portion of the semiconductor channel (e.g., using a configured concentration of boron) may increase a deselection voltage associated with relatively high channel resistance (e.g., compared to an undoped middle portion), which may support a memory device using a relatively more-positive deselection voltage (e.g., negative deselection voltage having a relatively lower magnitude, a ground voltage as a deselection voltage, a positive voltage as a deselection voltage, among other examples). Thus, the described techniques for cell selection transistor doping may be implemented to maintain cell selection transistors at a relatively high resistance in a manner that reduces refresh rates, reduces power consumption, or reduces complexity of circuitry associated with maintaining logic states in volatile memory cells, among other advantages.

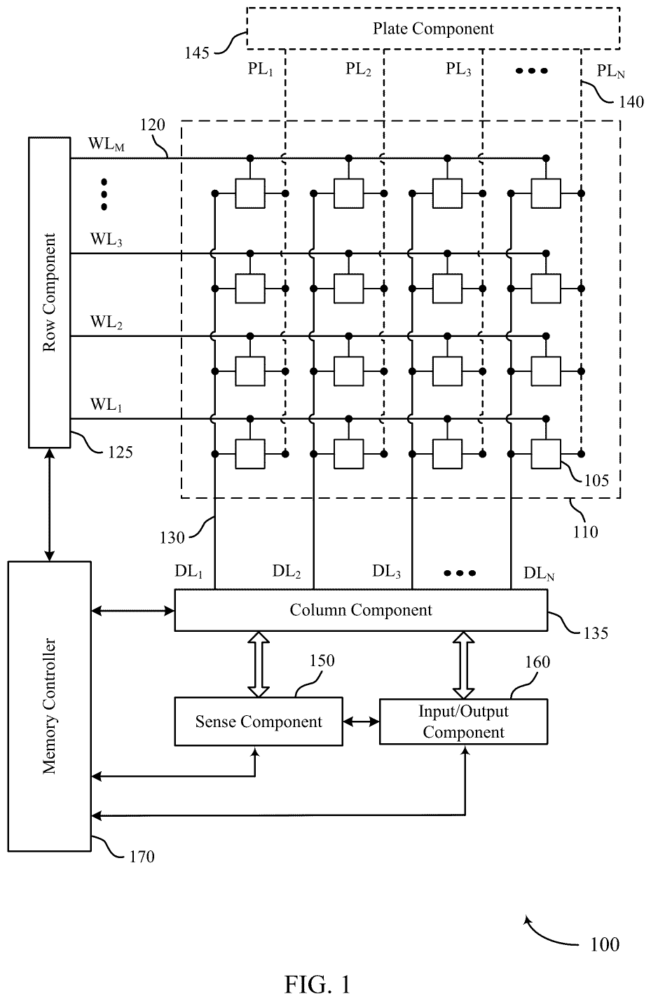

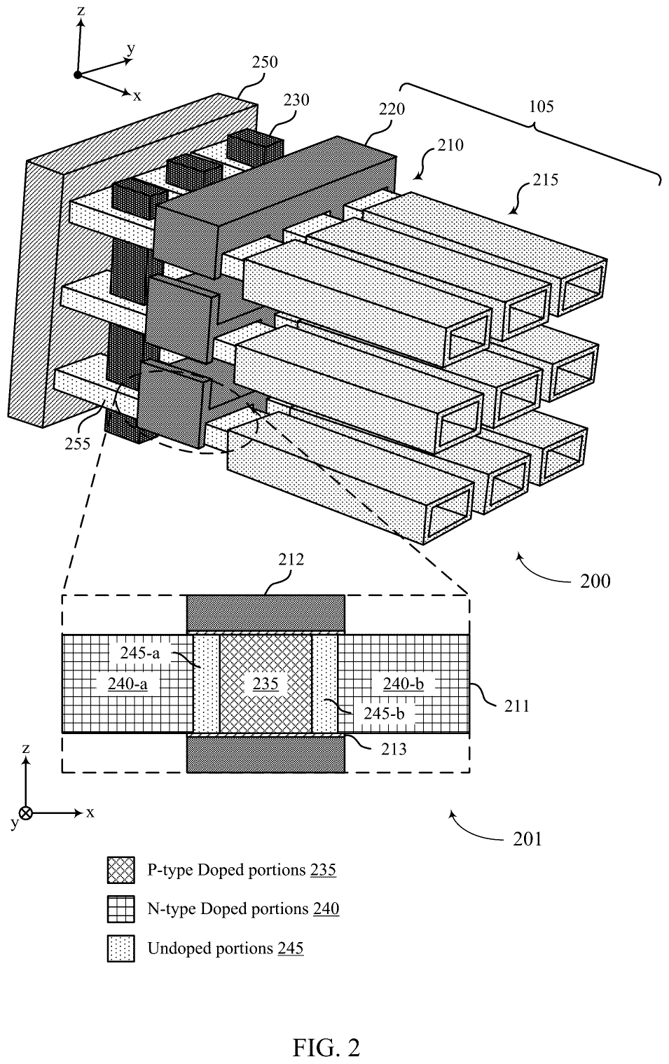

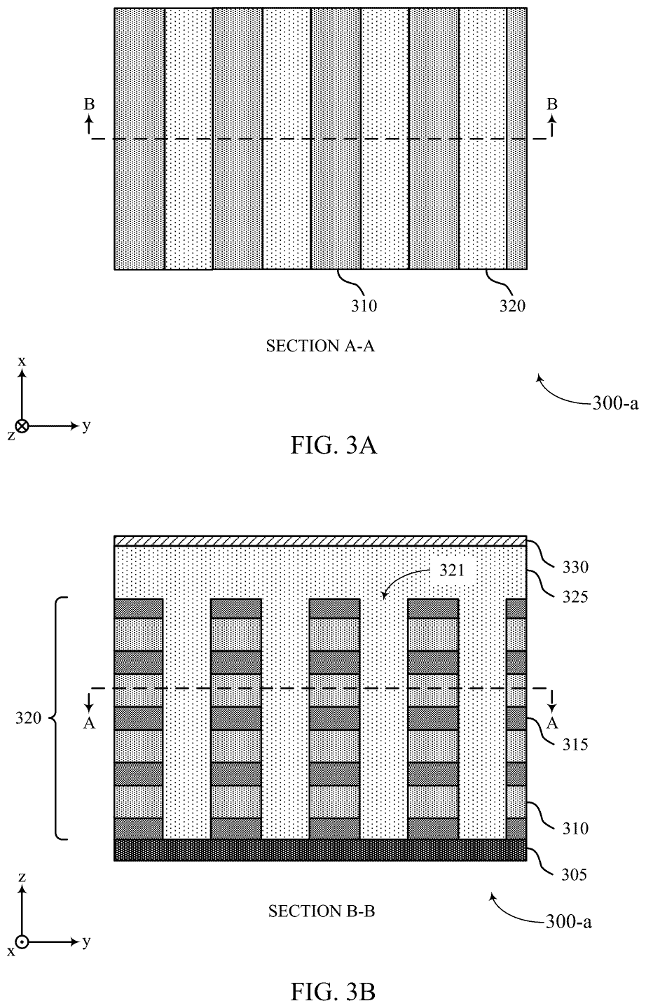

Features of the disclosure are initially illustrated and described in the context of a memory device, a memory array, and related circuitry with reference to FIGS. 1 and 2. These and other features of the disclosure are further illustrated and described in the context of processing steps and a flowchart with reference to FIGS. 3A through 7.

FIG. 1 shows an example of a memory device 100 that supports doping techniques for memory cell selection transistors in accordance with examples as disclosed herein. The memory device 100 may be referred to as a memory die or an electronic memory apparatus. The memory device 100 may include memory cells 105 that are programmable to store different logic states. In some cases, a memory cell 105 may be programmable to store two logic states, denoted a logic 0 and a logic 1. In some cases, a memory cell 105 may be programmable to store more than two logic states (e.g., as a multi-level cell). The memory cells 105 may be part of an array 110 (e.g., a memory array) of the memory device 100, where, in some examples, an array 110 may refer to a contiguous set of memory cells 105 (e.g., a contiguous set of elements of a semiconductor chip).

In some examples, a memory cell 105 may store an electric charge representative of the programmable logic states in a storage component (e.g., a capacitor, a capacitive memory element, a capacitive storage element). In some examples, a charged and uncharged capacitor may represent two logic states, respectively. In some other examples, a positively charged (e.g., a first polarity, a positive polarity) and negatively charged (e.g., a second polarity, a negative polarity) capacitor may represent two logic states, respectively. DRAM or FeRAM architectures may use such designs, and the capacitor employed may include a dielectric material with linear or para-electric polarization properties as an insulator. In some examples, different levels of charge of a capacitor may represent different logic states, which, in some examples, may support more than two logic states in a respective memory cell 105. In some examples, such as FeRAM architectures, a memory cell 105 may include a ferroelectric capacitor having a ferroelectric material as an insulating (e.g., non-conductive) layer between terminals of the capacitor. Different levels or polarities of polarization of a ferroelectric capacitor may represent different logic states (e.g., supporting two or more logic states in a respective memory cell 105).

In the example of memory device 100, each row of memory cells 105 may be coupled with one or more word lines 120 (e.g., WL₁ through WL_{M}), and each column of memory cells 105 may be coupled with one or more digit lines 130 (e.g., DL₁ through DL_{N}). Each of the word lines 120 and digit lines 130 may be an example of an access line of the memory device 100. In general, one memory cell 105 may be located at the intersection of (e.g., coupled with, coupled between) a word line 120 and a digit line 130. This intersection may be referred to as an address of a memory cell 105. A target or selected memory cell 105 may be a memory cell 105 located at the intersection of an activated or otherwise selected word line 120 and an activated or otherwise selected digit line 130.

In some architectures, a storage component of a memory cell 105 may be electrically isolated from a digit line 130 by a cell selection transistor, which, in some examples, may be referred to as a switching component or a selector device of or otherwise associated with the memory cell 105. A word line 120 may be coupled with the cell selection transistor (e.g., via a gate of the cell selection transistor), and may control the cell selection transistor of the memory cell 105. For example, activating a word line 120 may result in an electrical connection (e.g., a closed circuit) between a respective storage component of one or more memory cells 105 and one or more corresponding digit lines 130, which may be referred to as activating the one or more memory cells 105 or coupling the one or more memory cells 105 with a respective one or more digit lines 130. A digit line 130 may then be accessed to write to or read from the respective memory cell 105.

In some examples, memory cells 105 may also be coupled with one or more plate lines 140 (e.g., PL₁ through PL_{N}). In some examples, each of the plate lines 140 may be independently addressable (e.g., supporting individual selection or biasing). In some examples, the plurality of plate lines 140 may represent or be otherwise functionally equivalent with a common plate, or other common node (e.g., a plate node common to each of the memory cells 105 in the array 110). For implementations in which a memory cell 105 employs a capacitor for storing a logic state, a digit line 130 may provide access to a first terminal (e.g., a first plate) of the capacitor, and a plate line 140 may provide access to a second terminal (e.g., a second plate) of the capacitor. Although the plurality of plate lines 140 of the memory device 100 are shown as being parallel with the plurality of digit lines 130, in other examples, a plurality of plate lines 140 may be parallel with the plurality of word lines 120, or in any other configuration (e.g., a common planar conductor, a common plate layer, a common plate node).

Access operations such as reading, writing, rewriting, and refreshing may be performed on a memory cell 105 by activating (e.g., selecting) a word line 120, a digit line 130, or a plate line 140 coupled with the memory cell 105, which may include applying a voltage, a charge, or a current to the respective access line. After selecting a memory cell 105 (e.g., in a read operation), a resulting signal may be used to determine the logic state stored by the memory cell 105. For example, a memory cell 105 with a capacitive memory element storing a logic state may be selected, and the resulting flow of charge via an access line or resulting voltage of an access line may be detected to determine the programmed logic state stored by the memory cell 105.

Accessing memory cells 105 may be controlled using a row component 125 (e.g., a row decoder), a column component 135 (e.g., a column decoder), or a plate component 145 (e.g., a plate decoder), or a combination thereof. For example, a row component 125 may receive a row address from the memory controller 170 and activate a corresponding word line 120 based on the received row address. Similarly, a column component 135 may receive a column address from the memory controller 170 and activate a corresponding digit line 130. In some examples, such access operations may be accompanied by a plate component 145 biasing one or more of the plate lines 140 (e.g., biasing one of the plate lines 140, biasing some or all of the plate lines 140, biasing a common plate).

In some examples, the memory controller 170 may control operations (e.g., read operations, write operations, rewrite operations, refresh operations) of memory cells 105 using one or more components (e.g., row component 125, column component 135, plate component 145, sense component 150). In some cases, one or more of the row component 125, the column component 135, the plate component 145, and the sense component 150 may be co-located with or otherwise included as part of the memory controller 170. The memory controller 170 may generate row and column address signals to activate a desired word line 120 and digit line 130. The memory controller 170 may also generate or control various voltages or currents used during the operation of memory device 100.

A memory cell 105 may be written (e.g., programmed, set) by activating the relevant word line 120, digit line 130, or plate line 140 (e.g., via a memory controller 170). In other words, a logic state may be stored in a memory cell 105. A row component 125, column component 135, or plate component 145 may accept data, for example, via input/output component 160, to be written to the memory cells 105. In some examples, a write operation may be performed at least in part by a sense component 150, or a write operation may be configured to bypass a sense component 150.

In the case of a capacitive memory element, a memory cell 105 may be written by applying a voltage to (e.g., across) a capacitor, and then isolating the capacitor (e.g., isolating the capacitor from a voltage source used to write the memory cell 105, floating the capacitor) to store a charge in the capacitor associated with a desired logic state. In the case of ferroelectric memory, a ferroelectric memory element (e.g., a ferroelectric capacitor) of a memory cell 105 may be written by applying a voltage with a magnitude high enough to polarize the ferroelectric memory element (e.g., applying a saturation voltage) with a polarization associated with a desired logic state, and the ferroelectric memory element may be isolated (e.g., floating), or a zero net voltage may be applied across the ferroelectric memory element (e.g., grounding, virtually grounding, or equalizing a voltage across the ferroelectric memory element).

A memory cell 105 may be read (e.g., sensed) by a sense component 150 when the memory cell 105 is accessed (e.g., in cooperation with the memory controller 170) to determine a logic state written to or stored by the memory cell 105. For example, the sense component 150 may be configured to evaluate a current or charge transfer through or from the memory cell 105, or a voltage resulting from coupling the memory cell 105 with the sense component 150, responsive to a read operation. The sense component 150 may provide an output signal indicative of the logic state read from the memory cell 105 to one or more components (e.g., to the column component 135, the input/output component 160, to the memory controller 170).

A sense component 150 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 150 may include a collection of circuit elements that are repeated for each of a set or subset of digit lines 130 coupled with the sense component 150. For example, a sense component 150 may include a separate sensing circuit (e.g., a separate or duplicated sense amplifier, a separate or duplicated signal development component) for each of a set of digit lines 130 coupled with the sense component 150, such that a logic state may be separately detected for a respective memory cell 105 coupled with a respective one of the set of digit lines 130.

In some memory architectures, a logic state stored by a memory cell 105 may degrade, which may be based on accessing the memory cell 105 or other deterioration (e.g., charge leakage to or from a storage component), and a memory device 100 may be configured to perform rewrite or refresh operations to return the stored logic state to memory cell 105. In DRAM or FeRAM, for example, a capacitor of a memory cell 105 may be partially or completely discharged or depolarized during a sense operation, thereby corrupting the logic state that was stored in the memory cell 105. Thus, in some examples, the logic state stored in a memory cell 105 may be rewritten after an access operation. Further, activating a single word line 120, digit line 130, or plate line 140 may result in the discharge or other disturbance of other memory cells 105 coupled with the activated word line 120, digit line 130, or plate line 140. Additionally, or alternatively, charge may leak to or from a storage component (e.g., a capacitor) of a memory cell 105, causing a logic state stored by a memory cell to degrade over time. Thus, memory cells 105 may be rewritten (e.g., refreshed) after an access operation, or in accordance with a periodic interval, or both.

In some examples, charge leakage through a cell selection transistor of a memory cell 105 (e.g., between a storage component of the memory cell 105 and a digit line 130) may be related to a channel resistance of the cell selection transistor while a deselection voltage is applied to a gate of the cell selection transistor (e.g., as a gate voltage, as a voltage of a word line 120). For example, relatively lower channel resistance during deselection may be associated with relatively higher leakage and relatively higher channel resistance during deselection may be associated with relatively lower leakage. A deselection voltage for memory cells 105 may be selected to provide a relatively high channel resistance (e.g., a peak channel resistance) and therefore a relatively low charge leakage through the cell selection transistors while deselected.

In some cases, such as with an N—U—N cell selection transistor, a deselection voltage for relatively high channel resistance may be a negative voltage. Although N—U—N cell selection transistors may be relatively easier to manufacture than other types of cell selection transistors, including for three-dimensional arrays of memory cells 105 arranged above a substrate (e.g., above a semiconductor substrate, such as a crystalline silicon wafer), maintaining a deselection voltage at a negative voltage may involve relatively higher power consumption or relatively higher complexity than maintaining the deselection voltage at other voltages, such as a ground voltage. Further, although a ground voltage may be implemented for a deselection voltage in such architectures, the relatively lower resistance, and corresponding higher rate of charge leakage, may involve relatively higher rates of refresh to restore a charge level of charge-storing memory elements, which may be associated with relatively higher power consumption or relatively higher latency or processor load associated with performing refresh operations.

In accordance with examples as disclosed herein, cell selection transistors for a three-dimensional array of memory cells 105 may each include a semiconductor channel that is doped at a middle portion of the channel, which may support a deselection voltage for relatively high channel resistance that is relatively closer to or equal to a ground voltage than other transistor configurations. For example, the semiconductor channels may include a p-type doping (e.g., using a configured concentration of boron) at a middle portion of the channels that is between end portions that are doped with an n-type doping (e.g., using phosphorous, arsenic, or a combination thereof, among other examples of n-type doping), which may be implemented in a horizontal N—P—N cell selection transistor formed above a substrate. In some implementations, undoped regions of the semiconductor channels may be included between the n-type doped portions and the p-type doped portions (e.g., in an N—U—P—U—N cell selection transistor). In some examples, doping the middle portion of the semiconductor channel (e.g., using a configured concentration of boron) may increase a deselection voltage associated with relatively high channel resistance (e.g., compared to an undoped portion), which may support a memory device 100 using a relatively more-positive deselection voltage (e.g., a negative deselection voltage having a relatively lower magnitude, a ground voltage as a deselection voltage, a positive voltage as a deselection voltage, among other examples). Thus, the described techniques for cell selection transistor doping may be implemented by a memory device 100 to maintain cell selection transistors at a relatively high resistance in a manner that reduces refresh rates, reduces power consumption, or reduces complexity of circuitry associated with maintaining logic states in volatile memory cells, among other advantages.

In addition to applicability in memory systems as described herein, doping techniques for memory cell selection transistors may be generally implemented to improve the sustainability of various electronic devices and systems. As the use of electronic devices has become increasingly widespread, the amount of energy used and environmental implications associated with production of electronic devices and device operation has increased. Further, waste associated with disposal of electronic devices may also be detrimental for various reasons. Implementing the techniques described herein may reduce the impacts related to electronic devices by reducing a power consumption associated with operating the memory array, which may reduce emissions associated with powering the electronic devices, and by extending the life of electronic devices, which may reduce electronic waste, among other benefits.

FIG. 2 shows an example of an array architecture 200 that supports doping techniques for memory cell selection transistors in accordance with examples as disclosed herein. The array architecture 200 may illustrate an example for implementing an array 110 in a memory device 100, which may include features formed above a substrate (not shown), such as features formed above a crystalline semiconductor wafer. Aspects of the array architecture 200 may be described with reference to an x-direction, a y-direction, and a z-direction of the illustrated coordinate systems, including the cross-sectional view of a region 201 (e.g., a transistor region) as illustrated in an xz-plane. In some implementations, the x-direction may be a direction over (e.g., parallel to, above) the substrate, the y-direction may be another direction over (e.g., parallel to, above) the substrate, and the z-direction may be a direction away from the substrate (e.g., perpendicular to or otherwise away from a surface of the substrate, a height direction, a thickness direction).

The array architecture 200 illustrates an array of memory cells 105 (e.g., nine memory cells) arranged in a two-dimensional array along a yz-plane above the substrate. The example of array architecture 200 includes an arrangement of three memory cells 105 along the y-direction and three memory cells 105 along the z-direction, but the described techniques may be implemented for an arrangement of any quantity of memory cells 105 along the y-direction and any quantity of memory cells 105 along the z-direction, among other arrangements or directions. Such features may also be repeated (e.g., along the x-direction) to support the formation of a three-dimensional array of memory cells 105 over the substrate.

In the example of array architecture 200, each row of memory cells 105 may be associated with a respective word line conductor 220 that extends along the y-direction, where word line conductors 220 may be an example for implementing word lines 120. Further, each column of memory cells 105 may be associated with a respective digit line conductor 230 that extends along the z-direction, where digit line conductors 230 may be an example for implementing digit lines 130. Although the example of array architecture 200 illustrates an example of word line conductors 220 extending along the y-direction (e.g., a direction over a substrate) and digit line conductors 230 extending along the z-direction (e.g., a direction away from a substrate), in some other examples, word line conductors 220 may be configured to extend along the z-direction and digit line conductors 230 may be configured to extend along the y-direction, among other arrangements. The array architecture 200 may also include a plate conductor (not shown), which may be an example for implementing plate lines 140. In some examples, such a plate conductor may be a common plate (e.g., extending along the y-direction and along the z-direction, a planar plate conductor in a yz-plane) that is coupled with or otherwise associated with at least a subset if not all of the memory cells 105 (e.g., for each arrangement of memory cells 105 along a yz-plane, among other arrangements).

Each memory cell 105 may include a transistor 210 (e.g., a cell selection transistor) and a capacitor 215 (e.g., a storage component). In the example of array architecture 200, for a given memory cell 105, a respective transistor 210 and a respective capacitor 215 may be arranged along the x-direction. A capacitor 215 may be implemented with various arrangements of a dielectric material or ferroelectric material between the transistor 210 and the plate conductor (e.g., providing a capacitance between a channel of the transistor 210 and the plate conductor).

Each transistor 210 may include a channel 211 (e.g., as part of a semiconductor material portion 255), a gate 212, and a gate dielectric 213 between the channel 211 and the gate 212 (e.g., as shown in the region 201) which, in some examples, may be configured in an n-type transistor configuration. Each channel 211 may extend along the x-direction, and may be coupled with (e.g., coupled between) a respective capacitor 215 and one of the digit line conductors 230. Each channel 211 may thus be operable to couple a respective capacitor 215 with one of the digit line conductors 230 (e.g., based on activating the channel 211, based on a applying a selection voltage to a gate 212 of the transistor 210). Each word line conductor 220 may thus be operable to couple capacitors 215 of a row of memory cells 105 (e.g., arranged along the y-direction) with a respective digit line conductor 230 of a set of digit line conductors 230 (e.g., arranged along the y-direction).

One or more gates 212 may be coupled with or be a portion of a word line conductor 220. In some examples, word line conductors 220 may be adjacent to channels 211 (e.g., along the z-direction, along the y-direction, or both), such that the word line conductors 220 may operate as pass-by gates for the transistors 210. In some other examples (not shown), each channel 211 may extend through one of the word line conductors 220, such that the word line conductors 220 may operate as all-around gates for transistors 210 (e.g., with a portion of one of the word line conductors 220 wrapping around each channel 211).

In some examples, the array architecture 200 may include a body contact 250, which may be implemented to stabilize a body potential (e.g., a bulk potential) of at least a portion of a memory die formed in accordance with the array architecture 200. A body contact 250 may include various materials, including conductor or semiconductor materials (e.g., metals, silicon, polysilicon, silicon-germanium, p-type doped silicon). In the illustrated example, the body contact 250 is shown as being coupled with (e.g., physically coupled with) semiconductor material portions 255. In some other examples, a body contact 250 may be isolated from (e.g., physically isolated from, electrically isolated from) semiconductor material portions 255. Further, in some examples, a body contact 250 may be omitted from the array architecture 200.

A row of memory cells 105 may be accessed by activating (e.g., biasing, with a selection voltage) a word line conductor 220, which may bias the gates 212 of the transistors 210 of the row of memory cells 105. Biasing the gates 212 may modulate (e.g., increase) a conductivity of the channels 211 of the transistors 210, thereby coupling each capacitor 215 of the row of memory cells 105 with a respective digit line conductor 230. In some examples, a selection voltage for biasing word line conductors 220 for such accessing may be selected or configured to be equal to or above a threshold voltage of the transistors 210.

To write a logic state to a memory cell 105, after activating a channel 211 of the corresponding transistor 210, a digit line conductor 230 and, in some examples, a plate conductor, may be biased to apply a write voltage to the capacitor 215 of the memory cell 105 via the activated channel 211, thereby charging the capacitor 215. Subsequently, a deselection voltage may be applied to the gate 212 such that the capacitor 215 may store a charge corresponding to a logic state of the memory cell 105 (e.g., associated with a polarity or magnitude of the write voltage). To read the logic state from the memory cell 105, the channel 211 may be activated to couple the capacitor 215 with the digit line conductor 230, and a voltage or other signal of the digit line conductor 230 (e.g., based on a charge sharing with the capacitor 215 via the activated channel 211) may be used to detect the stored logic state.

Although a transistor 210 may be deselected (e.g., by applying a deselection voltage to a gate 212) between a write operation and a read operation, which may substantially decouple capacitors 215 from the digit line conductors 230, charge may leak to or from a capacitors 215 via a channel 211 of the transistor 210 (e.g., related to a non-zero conductivity through the channel 211), which may degrade logic states stored by the capacitors 215. To support a relatively slower degradation of stored logic states related to charge leakage, a deselection voltage for memory cells 105 may be selected or configured to provide a relatively high resistance (e.g., a peak resistance) through channels 211 and therefore a relatively low charge leakage through the transistors 210.

In accordance with examples as disclosed herein, channels 211 may include a semiconductor material (e.g., of a semiconductor material portion 255) that is doped in a middle portion of the channels 211, which may support a deselection voltage for relatively high channel resistance (e.g., peak channel resistance) that is relatively closer to or equal to a ground voltage than other configurations. For example, each channel 211 may include a semiconductor material, such as silicon, which may be a contiguous semiconductor material with different doped regions along the channel 211 (e.g., along the x-direction). In some examples, the semiconductor material may be formed in a crystalline arrangement that is contiguous along the channel 211 (e.g., by way of epitaxial formation of the semiconductor material above a substrate). Each channel 211 may include n-type doped portions 240 (e.g., portions of the semiconductor material having an n-type doping) and a p-type doped portion 235 (e.g., a portion of the semiconductor material having a p-type doping) between the n-type doped portions 240. In some examples, each channel 211 may also include undoped portions 245 between the n-type doped portions 240 and the p-type doped portion 235, such that the channel 211 may be configured in an N—U—P—U—N doping configuration. In some other examples (not shown), undoped portions 245 may be omitted, such that the channel 211 may be configured in an N—P—N doping configuration. Although illustrative boundaries of respective portions are shown along the channel 211 (e.g., along the x-direction, relative to boundaries of a gate 212), such boundaries may be different than shown, including different locations of boundaries between portions, and different relative widths of respective portions, along the x-directions (e.g., relative to boundaries or widths of a gate 212 along the x-direction).

In some examples, the p-type doped portions 235 may be doped with boron in accordance with a concentration that supports a peak resistance of a channel 211 being achieved with a deselection voltage (e.g., at a gate 212) that is relatively near or equal to a ground voltage. For example, adding boron doping to an undoped semiconductor material to form the p-type doped portion 235 may shift (e.g., increase) a gate voltage associated with a peak resistance of the channel 211. In some examples, implementing boron as a p-type dopant may also have a relatively small effect on the level of the peak resistance itself, compared with other doping techniques that may induce a reduced level of peak resistance that accompanies such a shift in gate voltage. Thus, using boron doping in p-type doped portions 235 may support achieving a peak resistance in channels 211 with a relatively low gate voltage, as well as a relatively low leakage rate itself, the combination of which may support relatively low refresh rates and relatively low power consumption for biasing word line conductors 220 with a deselection voltage. In some examples, such channel characteristics may be supported with boron doping at a peak concentration along the x-direction that is between 1 e18 atoms of boron per cubic centimeter and 1 e19 atoms of boron per cubic centimeter (e.g., of the p-type doped portions 235). In some examples, such channel characteristics may be supported with boron doping at a peak concentration along the x-direction that is between 3 e18 atoms of boron per cubic centimeter and 5 e18 atoms of boron per cubic centimeter. Such channel characteristics may also be supported with various examples of dopants in the n-type doped portions 240, such as various concentrations of phosphorous, arsenic, or both, among other dopants or combinations thereof (e.g., in combination with the boron doping of the p-type doped portions 235).

Thus, in accordance with these and other examples, forming channels 211 above a substrate (e.g., for horizontal transistors 210) with n-type doped portions 240 and p-type doped portions 235 may support shifting a deselection voltage for peak channel resistance toward a more-positive voltage (e.g., from a relatively low negative voltage towards or beyond a ground voltage), while also maintaining a relatively high peak channel resistance itself. Such techniques may support a memory device 100 using a negative deselection voltage having a relatively lower magnitude, or using a ground voltage as a deselection voltage, or using a positive voltage as a deselection voltage, among other examples, compared to other techniques (e.g., compared to implementations of an N—U—N transistor configuration). Thus, the described techniques for doping transistors 210 may be implemented to maintain channels 211 at a relatively high resistance in a manner that reduces refresh rates, reduces power consumption, reduces latency, or reduces complexity of circuitry associated with maintaining logic states in memory cells 105, among other advantages.

FIG. 3A through 6B illustrate examples of fabrication operations (e.g., manufacturing operation) that may support doping techniques for memory cell selection transistors in accordance with examples as disclosed herein. For example, FIGS. 3A through 6B may illustrate aspects of sequences of operations for fabricating aspects of a material arrangement 300, which may be an example of implementing aspects of an array architecture 200 described with reference to FIG. 2, among other types of memory architectures. Each of FIGS. 3A and 3B, 4A and 4B, 5A and 5B, and 6A and 6B may illustrate aspects of the material arrangement 300 after different subsets of the fabrication operations for forming the material arrangement 300 (e.g., illustrated as a material arrangement 300-a after a first set of one or more fabrication operations, as a material arrangement 300-b after a second set of one or more fabrication operations, and so on). Each view of the figures may be described with reference to an x-direction, a y-direction, and a z-direction as illustrated, which may correspond to the respective directions described with reference to the array architecture 200.

The provided figures include section views that illustrate example cross-sections of the material arrangement 300. For example, a view “SECTION A-A” may be associated with a cross-section in an xy-plane (e.g., in accordance with a cut plane A-A) through a portion of the material arrangement 300, and a view “SECTION B—B” may be associated with a cross-section in a yz-plane (e.g., in accordance with a cut plane B—B) through a portion of the material arrangement 300. Each of the related regions, illustrated by their respective cross sections, may extend for some distance (e.g., along a direction into the page, out of the page, or both).

Operations illustrated in and described with reference to FIGS. 3A through 6B may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques. In some examples, operations performed by such a manufacturing system may be supported by a process controller or its components as described herein.

Although aspects of the material arrangement 300 illustrate examples of relative dimensions and quantities of various features, aspects of the material arrangement 300 may be implemented with other relative dimensions or quantities of such features in accordance with examples as disclosed herein. In the following description of the material arrangement 300, some methods, techniques, processes, and operations may be performed in different orders, or at different times, or otherwise modified. Further, some operations for fabricating a material arrangement 300 (e.g., for fabrication in accordance with an array architecture 200) may be omitted from the described fabrication operations, or other operations may be added to the described fabrication operations.

FIGS. 3A and 3B illustrate an example of the material arrangement 300 (e.g., as a material arrangement 300-a) after a first set of one or more fabrication operations. For example, the material arrangement 300-a may include multiple portions of a material 310 formed above a substrate 305 (e.g., a semiconductor substrate, a semiconductor wafer). The material 310 may be a semiconductor material (e.g., silicon or another semiconductor material), and the portions of material 310 may be arranged in an array along the y-direction and along the z-direction. The portions of the material 310 may be examples of semiconductor material portions 255, and at least some of the portions of the material 310 may be associated with channels 211 of transistors 210, with the channels 211 being aligned along the x-direction.

In some examples, the first set of operations may include forming a stack 320 over the substrate 305, which may include alternating layers (e.g., layers along an xy-plane, alternating and having a thickness along the z-direction) of the material 310 and a material 315. In some examples, the material 315 may be a sacrificial material that supports forming an isolation (e.g., electrical isolation, physical separation) between portions of the material 310, among other operations for forming the material arrangement 300. In some examples, forming the stack 320 may implement epitaxial formation techniques (e.g., epitaxial deposition). For example, the substrate 305 may have a crystalline atomic arrangement, and the crystalline arrangement of the substrate 305 may be translated through (e.g., contiguous through) the layers of the material 310 and the material 315 of the stack 320. To support such techniques, the material 310 and the material 315 may be selected to support translation of the crystalline arrangement from the substrate 305 as the layers are formed (e.g., deposited) along the z-direction (e.g., across boundaries between and through layers of the material 310 and the material 315). In some examples, the substrate 305 may be the same material as the material 310 (e.g., silicon or other semiconductor), and the material 315 may be a compound of the material 310 or another material that is otherwise compatible for translating the atomic arrangement of the substrate 305. For example, the material 310 may be silicon (e.g., epitaxial silicon) and the material 315 may be silicon germanium (e.g., epitaxial silicon germanium). In some examples, the material 310 and the material 315 may also be selected to support differential processing techniques, such as selecting the material 315 to support being preferentially removed while maintaining portions of the material 310.

In some examples, the first set of operations may also include forming trenches 321 through at least a portion of the stack 320 (e.g., towards, until, or through a portion of the substrate 305, along the z-direction), which may be filled with a material 325. Thus, the portions of the material 310 may be separated along the z-direction by way of the formation of alternating layers of the material 310 and the material 315 along the z-direction, and the portions of material 310 may be separated along the y-direction by way of the formation of the trenches 321. Each portion of the material 310 may have a contiguous crystalline atomic arrangement (e.g., along the x-direction, through a channel 211 that includes the portions of material 310), whether due to the epitaxial formation of the material 310 or some other means.

In some examples, the material 325 may be a dielectric material (e.g., an oxide material such as silicon oxide, a nitride material such as silicon nitride) which may provide an electrical isolation between features of the material arrangement 300. Additionally, or alternatively, at least a portion of the material 325 may be a sacrificial material that is removed (e.g., partially, entirely) in later operations. In some examples, a layer of the material 325, among other materials (not shown), may be formed over the stack 320. In some examples, a material 330 may be deposited over the stack 320 (e.g., over the additional layer of material 325), which may support a masking functionality for subsequent operations (e.g., photolithography operations), such that the material 330 may be associated with protecting features of the material arrangement 300 from the subsequent operations.

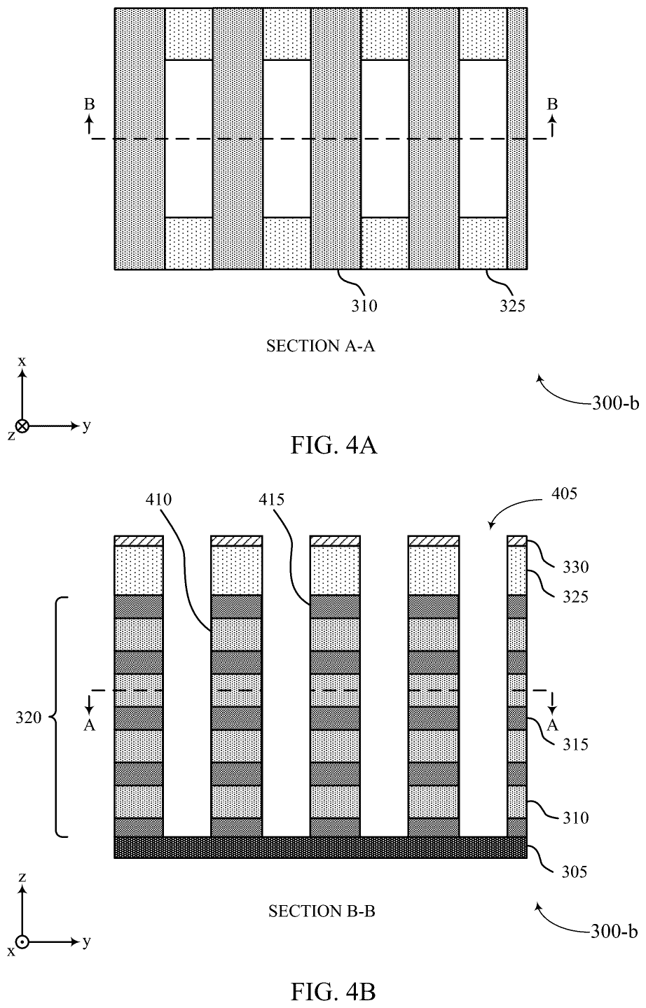

FIGS. 4A and 4B illustrate an example of the material arrangement 300 (e.g., as a material arrangement 300-b) after a second set of one or more fabrication operations. For example, the second set of operations may include removing portions of the material 330 to form openings through the material 330 (e.g., openings in an xy-plane, extending through the material 330 along the z-direction). Subsequently, cavities 405 may be formed through the openings by removing at least portions of the material 325 along the z-direction and, in some examples, also removing some portions of the material 310, the material 315, or both. In some examples, the openings through the material 330 and the cavities 405 may be formed along (e.g., aligned with) the trenches 321 (e.g., as a portion of the trenches 321 along the x direction).

Forming the cavities 405 may implement a high aspect ratio material removal process (e.g., a dry etching process) to preferentially remove one or more materials along the z-direction, which may be configured to preferentially remove the material 325 (e.g., to reduce removal of the material 310 or the material 315). In some examples, the cavities 405 may extend through the stack 320 (e.g., along the z-direction) and, in some examples, may remove a portion of the substrate 305. The cavities 405 may be formed between portions of the material 310 and portions of the material 315 (e.g., along the y-direction), which may expose sidewalls 410 of the material 310 and sidewalls 415 of the material 315 (e.g., sidewalls generally along xz-planes).

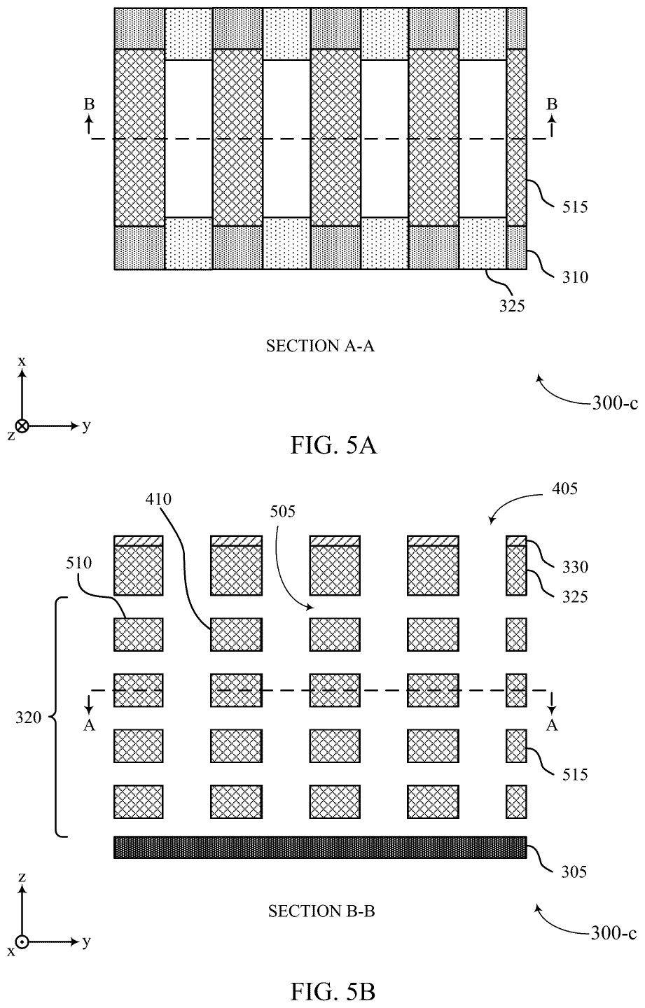

FIGS. 5A and 5B illustrate an example of the material arrangement 300 (e.g., as a material arrangement 300-c) after a third set of one or more fabrication operations. For example, the third set of operations may include removing portions of the material 315 from between the portions of the material 310. In some examples, the material 315 may be removed via the openings through the material 330 using an omnidirectional material removal operation (e.g., a wet etching operation, an exhume operation), which may be configured to preferentially remove the material 315 rather than the material 310, the material 325, or the substrate 305. Thus, the removal of the material 315 may form cavities 505 (e.g., voids) between layers of the material 310 (e.g., between portions of the material 310, along the z-direction), exposing sidewalls 510 of the portions of the material 310 (e.g., sidewalls generally along xy-planes, top and bottom sidewalls). Thus, the forming of cavities 405 and cavities 505 may expose sidewalls (e.g., sidewalls 410, sidewalls 510) around each portion of the material 310. As illustrated in the material arrangement 300-c, the portions of the material 310 may be supported at ends along the x-direction but, as shown in FIG. 5B, may be unsupported between the ends.

The third set of operations may also include doping the portions of material 310 via the exposed sidewalls 410 and 510 to form doped portions 515, which may be examples of p-type doped portions 235 for channels 211. For example, the portions of material 310 may be exposed to a p-type dopant, such as boron (e.g., gas phase boron), to form a configured concentration of dopant in the doped portions 515. The concentration of dopant may be controlled by various techniques, such as duration of dopant exposure, a temperature during dopant exposure, dopant concentration (e.g., gas concentration), and other techniques or combinations thereof. In some examples, a peak concentration of the dopant (e.g., boron) in the doped portions 515 (e.g., along the x-direction) may be between 1 e18 atoms per cubic centimeter and 1 e19 atoms per cubic centimeter. In some examples, a peak concentration of the dopant (e.g., boron) in the doped portions 515 (e.g., along the x-direction) may be between 3 e18 atoms per cubic centimeter and 5 e18 atoms per cubic centimeter.

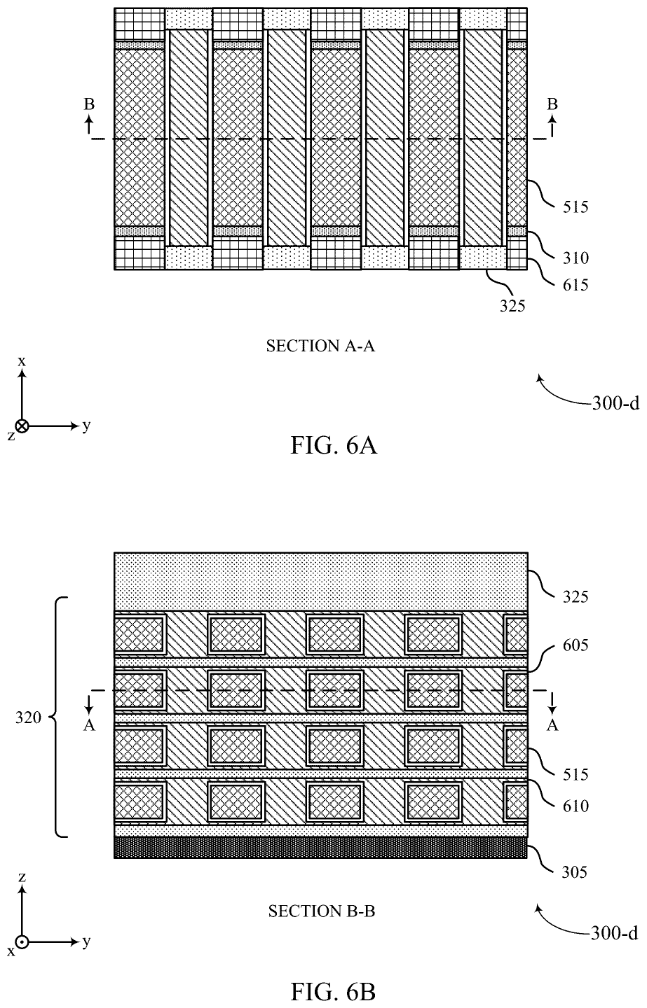

FIGS. 6A and 6B illustrate an example of the material arrangement 300 (e.g., as a material arrangement 300-d) after a fourth set of fabrication operations. For example, the fourth set of operations may include forming gates around the doped portions 515 or adjacent to the doped portions 515. In some examples, such techniques may include forming a material 605 around the doped portions 515 (e.g., forming the material 605 on sidewalls 410 and sidewalls 510), which may be an example of forming gate dielectrics 213. The material 605 may be an oxide material (e.g., silicon oxide), a nitride material (e.g., silicon nitride), or another dielectric material, which may be the same as the material 325 or different than the material 325 (e.g., to support subsequent differential processing). In various examples, such techniques may involve a formation of the material 605 via openings for the cavities 405, or via openings that are widened (e.g., along the x-direction) relative to the openings for the cavities 405, or via openings formed separately from the openings for the cavities 405. Thus, in various examples, the material 605 may span different extents along the x-direction than doped portions 515.

In some examples, forming gates may include forming a material 610 (e.g., a gate material, a gate conductor) around the doped portions 515, which may be an example of forming gates 212, or word line conductors 220, or both. In various examples, the material 610 may be a conductor material (e.g., tungsten, copper) or a semiconductor material (e.g., silicon, polycrystalline silicon). In the example of material arrangement 300-d, the material 610 may be formed around each of the doped portions 515 (e.g., as an all-around gate). In some other examples (not shown), the gate material 610 may be formed adjacent the doped portions 515 (e.g., along the y-direction, along the z-direction, or both, as a pass-by gate). In various examples, the material 610 may span different extents along the x-direction than the material 605, than the doped portions 515, or both. In the example of material arrangement 300-d, the material 610 may be contiguous between doped portions 515 along the y-direction, which may support the formation of word line conductors 220 along the y-direction. In some other examples (not shown), the material 610 may alternatively be contiguous between doped portions 515 along the z-direction (e.g., forming word line conductors 220 that extend along the z-direction). Formation of word line conductors 220 may be implemented in accordance with various techniques, which may include forming the material 610 and forming another material, which may be the same as or different than the material 610, and which may be formed in different steps (e.g., to provide a conductivity between separately-formed portions of the material 610).

The fourth set of operations may also include forming doped portions 615, which may be examples of n-type doped portions 240. The doped portions 615 may be formed by various techniques, which may be similar to or different than forming doped portions 515. For example, the fourth set of operations may include exposing sidewalls of the portions of the material 310 along a different region of the portions of material 310 (e.g., along the x-direction), which may include various techniques for forming cavities or voids, and doping the material 310 via the exposed sidewalls. In some examples, the doped portions 615 may be doped with phosphorous, arsenic, or a combination thereof. In some examples, doped portions 615 may be separated from doped portions 515 by an undoped portion of the material 310 (e.g., to form an N—U—P—U—N doping arrangement for channels 211), or doped portions 615 may be adjacent to doped portions 515 (e.g., without undoped portions of the material 310 between them, not shown, to form an N—P—N doping arrangement for channels 211). In some examples, doped portions 615 on a first side of doped portions 515 along the x-direction may be coupled (e.g., physically, electrically) with capacitors 215 (not shown) and doped portions 615 on a second side of doped portions 515 along the x-direction may be coupled with digit line conductors 230 (not shown, which may extend along the z-direction), which may be formed in accordance with various techniques (e.g., before, during, or after the fourth set of operations). In some examples, gaps between the other described features of the material arrangement 300 may be filled with a dielectric material (e.g., to provide an electrical isolation), which may implement a further formation of the material 325, among other examples.

Thus, in accordance with these and other examples, a material arrangement such as the material arrangement 300 may be formed to support channels 211 above the substrate 305 (e.g., horizontal channels, along the x-direction) with at least doped portions 515 between doped portions 615, which may support shifting a deselection voltage for peak resistance of the channels 211 toward a more-positive voltage, while also maintaining a relatively high peak resistance of the channels 211. Such techniques may support a memory device 100 using a deselection voltage that is relatively more-positive than other techniques. Thus, aspects of the material arrangement 300 may be implemented to maintain channels 211 at a relatively high resistance in a manner that reduces refresh rates, reduces power consumption, reduces latency, or reduces complexity of circuitry associated with maintaining logic states in memory cells 105, among other advantages.

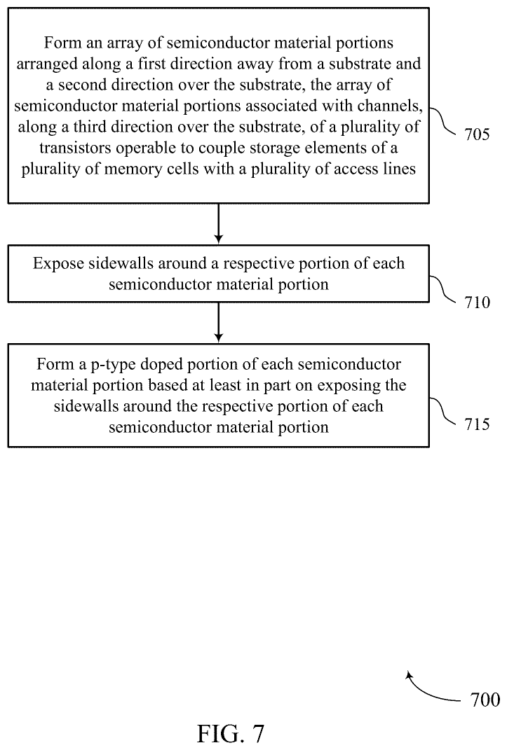

FIG. 7 shows a flowchart illustrating a method 700 that supports doping techniques for memory cell selection transistors in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method may include forming an array of semiconductor material portions arranged along a first direction away from a substrate and a second direction over the substrate, the array of semiconductor material portions associated with channels, along a third direction over the substrate, of a plurality of transistors operable to couple storage elements of a plurality of memory cells with a plurality of access lines.

At 710, the method may include exposing sidewalls around a respective portion of each semiconductor material portion.

At 715, the method may include forming a p-type doped portion of each semiconductor material portion based at least in part on exposing the sidewalls around the respective portion of each semiconductor material portion.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming an array of semiconductor material portions arranged along a first direction away from a substrate and a second direction over the substrate, the array of semiconductor material portions associated with channels, along a third direction over the substrate, of a plurality of transistors operable to couple storage elements of a plurality of memory cells with a plurality of access lines; exposing sidewalls around a respective portion of each semiconductor material portion; and forming a p-type doped portion of each semiconductor material portion based at least in part on exposing the sidewalls around the respective portion of each semiconductor material portion.

Aspect 2: The method or apparatus of aspect 1, where forming the p-type doped portions includes operations, features, circuitry, logic, means, or instructions, or any combination thereof for doping each of the semiconductor material portions with boron at a peak concentration along the third direction that is between 1 e18 atoms per cubic centimeter and 1 e19 atoms per cubic centimeter.

Aspect 3: The method or apparatus of aspect 1, where forming the p-type doped portions includes operations, features, circuitry, logic, means, or instructions, or any combination thereof for doping each of the semiconductor material portions with boron at a peak concentration along the third direction that is between 3 e18 atoms per cubic centimeter and 5 e18 atoms per cubic centimeter.

Aspect 4: The method or apparatus of any of aspects 1 through 3, further including operations, features, circuitry, logic, means, or instructions, or any combination thereof for forming a first n-type doped portion of each semiconductor material portion and a second n-type doped portion of each semiconductor material portion, where the p-type doped portion of each semiconductor material portion is between the first n-type doped portion and the second n-type doped portion.

Aspect 5: The method or apparatus of aspect 4, where each semiconductor material portion of the plurality of transistors includes an undoped portion between the first n-type doped portion and the p-type doped portion, or between the second n-type doped portion and the p-type doped portion, or both.

Aspect 6: The method or apparatus of any of aspects 1 through 5, further including operations, features, circuitry, logic, means, or instructions, or any combination thereof for forming a stack of material layers over the substrate, the stack of material layers including alternating layers of the semiconductor material and a second material, and forming the array of semiconductor material portions based at least in part on forming trenches along the third direction and through the stack of material layers.

Aspect 7: The method or apparatus of aspect 6, where the semiconductor material includes epitaxial silicon and the second material includes epitaxial silicon germanium.

Aspect 8: The method or apparatus of any of aspects 6 through 7, where exposing the sidewalls around the respective portion of each semiconductor material portion includes operations, features, circuitry, logic, means, or instructions, or any combination thereof for forming cavities between layers of the semiconductor material based at least in part on removing the second material from between the layers of the semiconductor material.

Aspect 9: The method or apparatus of any of aspects 1 through 8, further including operations, features, circuitry, logic, means, or instructions, or any combination thereof for forming gates for each of the plurality of transistors based at least in part on forming a gate material around each of the respective portions of the semiconductor material portions, or adjacent to each of the respective portions of the semiconductor material portions along the first direction, after forming the p-type doped portion.

It should be noted that the methods described herein are possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: An apparatus, including: an array of memory cells arranged along a first direction away from a substrate and a second direction over the substrate, each memory cell of the array including a respective capacitor and a respective cell selection transistor having a channel extending along a third direction over the substrate; a plurality of digit line conductors; and a plurality of word line conductors operable to couple the capacitors, of a respective subset of memory cells of the array, with the plurality of digit lines based at least in part on activating the channels of the cell selection transistors of the respective subset of memory cells, where, for each memory cell of the array, the channel of the respective cell selection transistor includes: a first channel portion including a semiconductor material having an n-type doping; a second channel portion including the semiconductor material having the n-type doping; and a third channel portion, between the first channel portion and the second channel portion along the third direction, including the semiconductor material having a p-type doping.

Aspect 11: The apparatus of aspect 10, where the p-type doping includes boron doping.

Aspect 12: The apparatus of any of aspects 10 through 11, where for each memory cell of the array, the third channel portion includes boron at a peak concentration along the third direction that is between 1 e18 atoms per cubic centimeter and 1 e19 atoms per cubic centimeter.

Aspect 13: The apparatus of any of aspects 10 through 11, where for each memory cell of the array, the third channel portion includes boron at a peak concentration along the third direction that is between 3 e18 atoms per cubic centimeter and 5 e18 atoms per cubic centimeter.

Aspect 14: The apparatus of any of aspects 10 through 13, where, for each memory cell of the array, the channel of the respective cell selection transistor further includes: a fourth channel portion, between the first channel portion and the third channel portion along the third direction, including the semiconductor material without doping; and a fifth channel portion, between the second channel portion and the third channel portion along the third direction, including the semiconductor material without doping.

Aspect 15: The apparatus of any of aspects 10 through 14, where the n-type doping includes phosphorous doping, arsenic doping, or a combination thereof.

Aspect 16: The apparatus of any of aspects 10 through 15, where each digit line conductor of the plurality of digit line conductors extends along the first direction, and each word line conductor of the plurality of word line conductors extends along the second direction.

Aspect 17: The apparatus of any of aspects 10 through 16, further including: a plate conductor extending along the first direction and the second direction and coupled with the respective capacitor of each of the memory cells of the array.

Aspect 18: The apparatus of any of aspects 10 through 17, where for each memory cell of the array, the semiconductor material is ordered in a crystalline arrangement that is contiguous across the first channel portion, the second channel portion, and the third channel portion.

An apparatus is described. The following provides an overview of aspects of the apparatus as described herein:

Aspect 19: An apparatus, including: a memory cell including a capacitor and a cell selection transistor having a channel extending along a first direction over a substrate, the channel including a first portion of a semiconductor material having an n-type doping, a second portion of the semiconductor material having an n-type doping, and a third portion of the semiconductor material, between the first portion and the second portion, having a p-type doping; a first access line conductor extending along a second direction away from the substrate; and a second access line conductor extending along a third direction over the substrate and operable to couple the capacitor with the first access line conductor via the channel of the cell selection transistor based at least in part on a voltage of the second access line conductor.

Aspect 20: The apparatus of aspect 19, where the channel further includes: a fourth portion of the semiconductor material, between the first portion and the third portion, without doping; and a fifth portion of the semiconductor material, between the second portion and the third portion, without doping.

Aspect 21: The apparatus of any of aspects 19 through 20, where the p-type doping includes boron and the n-type doping includes phosphorous, arsenic, or a combination thereof.

Aspect 22: The apparatus of any of aspects 19 through 21, where the p-type doping includes boron at a peak concentration along the third direction that is between 1 e18 atoms per cubic centimeter and 1 e19 atoms per cubic centimeter.

Aspect 23: The apparatus of any of aspects 19 through 21, where the p-type doping includes boron at a peak concentration along the third direction that is between 3 e18 and 5 e18 atoms of boron per cubic centimeter.

Aspect 24: The apparatus of any of aspects 19 through 23, where the channel extends along the first direction through the second access line conductor.

Aspect 25: The apparatus of any of aspects 19 through 24, where the second access line conductor is adjacent to the channel along the second direction.

Aspect 26: The apparatus of any of aspects 19 through 25, where the semiconductor material is ordered in a crystalline arrangement that is contiguous across the first portion, the third portion, and the second portion.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals can be communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected with other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
an array of memory cells arranged along a first direction away from a substrate and a second direction over the substrate, each memory cell of the array comprising a respective capacitor and a respective cell selection transistor having a channel extending along a third direction over the substrate;
a plurality of digit line conductors; and
a plurality of word line conductors operable to couple the capacitors, of a respective subset of memory cells of the array, with the plurality of digit lines based at least in part on activating the channels of the cell selection transistors of the respective subset of memory cells,
wherein, for each memory cell of the array, the channel of the respective cell selection transistor comprises:
a first channel portion comprising a semiconductor material having an n-type doping;
a second channel portion comprising the semiconductor material having the n-type doping; and
a third channel portion, between the first channel portion and the second channel portion along the third direction, comprising the semiconductor material having a p-type doping.

2. The apparatus of claim 1, wherein the p-type doping comprises boron doping.

3. The apparatus of claim 1, wherein for each memory cell of the array, the third channel portion comprises boron at a peak concentration along the third direction that is between 1 e18 atoms per cubic centimeter and 1 e19 atoms per cubic centimeter.

4. The apparatus of claim 1, wherein for each memory cell of the array, the third channel portion comprises boron at a peak concentration along the third direction that is between 3 e18 atoms per cubic centimeter and 5 e18 atoms per cubic centimeter.

5. The apparatus of claim 1, wherein, for each memory cell of the array, the channel of the respective cell selection transistor further comprises:
a fourth channel portion, between the first channel portion and the third channel portion along the third direction, comprising the semiconductor material without doping; and
a fifth channel portion, between the second channel portion and the third channel portion along the third direction, comprising the semiconductor material without doping.

6. The apparatus of claim 1, wherein the n-type doping comprises phosphorous doping, arsenic doping, or a combination thereof.

7. The apparatus of claim 1, wherein:
each digit line conductor of the plurality of digit line conductors extends along the first direction; and
each word line conductor of the plurality of word line conductors extends along the second direction.

8. The apparatus of claim 1, further comprising:
a plate conductor extending along the first direction and the second direction and coupled with the respective capacitor of each of the memory cells of the array.

9. The apparatus of claim 1, wherein for each memory cell of the array, the semiconductor material is ordered in a crystalline arrangement that is contiguous across the first channel portion, the second channel portion, and the third channel portion.

10. An apparatus, comprising:
a memory cell comprising a capacitor and a cell selection transistor having a channel extending along a first direction over a substrate, the channel comprising a first portion of a semiconductor material having an n-type doping, a second portion of the semiconductor material having an n-type doping, and a third portion of the semiconductor material, between the first portion and the second portion, having a p-type doping;
a first access line conductor extending along a second direction away from the substrate; and
a second access line conductor extending along a third direction over the substrate and operable to couple the capacitor with the first access line conductor via the channel of the cell selection transistor based at least in part on a voltage of the second access line conductor.

11. The apparatus of claim 10, wherein the channel further comprises:
a fourth portion of the semiconductor material, between the first portion and the third portion, without doping; and
a fifth portion of the semiconductor material, between the second portion and the third portion, without doping.

12. The apparatus of claim 10, wherein:
the p-type doping comprises boron; and
the n-type doping comprises phosphorous, arsenic, or a combination thereof.

13. The apparatus of claim 10, wherein the p-type doping comprises boron at a peak concentration along the third direction that is between 1 e18 atoms per cubic centimeter and 1 e19 atoms per cubic centimeter.

14. The apparatus of claim 10, wherein the p-type doping comprises boron at a peak concentration along the third direction that is between 3 e18 and 5 e18 atoms of boron per cubic centimeter.

15. The apparatus of claim 10, wherein the channel extends along the first direction through the second access line conductor.

16. The apparatus of claim 10, wherein the second access line conductor is adjacent to the channel along the second direction.

17. The apparatus of claim 10, wherein the semiconductor material is ordered in a crystalline arrangement that is contiguous across the first portion, the third portion, and the second portion.

18. A method, comprising:
forming an array of semiconductor material portions arranged along a first direction away from a substrate and a second direction over the substrate, the array of semiconductor material portions associated with channels, along a third direction over the substrate, of a plurality of transistors operable to couple storage elements of a plurality of memory cells with a plurality of access lines;
exposing sidewalls around a respective portion of each semiconductor material portion; and
forming a p-type doped portion of each semiconductor material portion based at least in part on exposing the sidewalls around the respective portion of each semiconductor material portion.

19. The method of claim 18, further comprising:
forming a first n-type doped portion of each semiconductor material portion and a second n-type doped portion of each semiconductor material portion, wherein the p-type doped portion of each semiconductor material portion is between the first n-type doped portion and the second n-type doped portion.

20. The method of claim 19, wherein each semiconductor material portion of the plurality of transistors comprises an undoped portion between the first n-type doped portion and the p-type doped portion, or between the second n-type doped portion and the p-type doped portion, or both.
